(19) United States
(12) Patent Application Publication
(10) Pub. No.: US 2025/0144861 A1
(43) Pub. Date: May 8, 2025

(54) PLASTIC INJECTION MOLDING FOR VENTED CYLINDER DEVICES

(71) Applicant: Comcast Cable Communications, LLC, Philadelphia, PA (US)

(72) Inventors: Henry HOMZA, Philadelphia, PA (US); FangYu ROSENWALD, Philadelphia, PA (US)

(21) Appl. No.: 18/500,856

(22) Filed: Nov. 2, 2023

(51) Int. Cl. B29C 45/26; B29L 31/34; H05K 5/02

(52) U.S. Cl. CPC B29C 45/2628; H05K 5/0213; B29L 2031/3481

(57) ABSTRACT

Disclosed herein are systems and methods for creating an encasing or shell for one or more electronic devices. An encasing for one or more electronic devices may be made from a single cavity injection mold tool. The single cavity plastic injection mold tool may be used to mold a sheet with one or more ventilation apertures. A shell may be formed by overlapping or contacting a first end of the sheet to a second end of the sheet. A cavity for the electronic device may be defined by coupling a first endcap and a second endcap to the shell. This method can reduce wasted material in the injection molding process and can provide for efficient manufacturing of encasings for one or more electronic devices.

### BACKGROUND

Manufacturing encasings for electronic devices via injection molding may present several challenges, particularly when the encasing is designed to include openings in its structure. For example, to injection mold a hollow three-dimensional object, such as an encasing, a multi-part molding process is often required. The process may involve separately molding at least two mold parts that represent two halves of the desired object, and then later joining them together to create the desired object. This process is undesirable because of its time inefficiencies, manufacturing complexity, and introduction of potential product imperfections during the joining step.

As another example, if openings in the structure of a three-dimensional object are desired, such as ventilation slots, these openings may create undesirable geometries for injection molding. For example, the openings in the surface of the object may introduce protrusions, holes, cavities, and recessed areas that inhibit the object part from being cleanly removed (e.g., due to non-perpendicular alignment to the mold's parting line). To avoid these geometries, the desired three-dimensional object can be further divided into smaller, individual pieces that allow for clean perpendicular pulls from the mold. However, this approach may significantly increase the number of individually mold pieces that later need to be joined. Lastly, while multi-cavity molds can sometimes mitigate these time inefficiencies by producing the multiple parts in one mold cycle, this method may result in a considerable amount of waste material and still may not allow for openings in the structure of the object.

### SUMMARY

Disclosed herein are systems and methods for creating an encasing or shell for one or more electronic devices via injection molding. A sheet with one or more ventilation apertures may be injection molded from a single cavity plastic injection mold. The sheet may be formed into a shell by overlapping or contacting a first end of the sheet to a second end of the sheet. A cavity for the electronic device may be defined by coupling a first endcap and a second endcap to the shell. Thus, an encasing for an electronic device may be created from a single-cavity injection mold. Enabling the manufacture of encasings from a single cavity injection molding tool may avoid reliance on other multi-part and multi-mold injection molding processes, such as those that involve a multi-cavity injection molding tool, thereby requiring less injection material and tooling. Further, forming the encasing by molding a substantially two-dimensional sheet may facilitate more uniform apertures or ventilation slots, and a wider variety of aperture or slot dimensions or locations, along the surface of the encasing.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to limitations that solve any or all disadvantages noted in any part of this disclosure.

### BRIEF DESCRIPTION OF THE DRAWINGS

The accompanying drawings, which are incorporated in and constitute a part of this specification, illustrate embodiments or various aspects thereof, and together with the description, serve to explain the principles of the methods and systems:

FIG. 1 shows an example sheet;

FIG. 2 shows an example sheet;

FIG. 3 shows an example sheet;

FIG. 4 shows an example sheet;

FIG. 5 shows an example shell;

FIG. 6 shows an example shell;

FIG. 7 shows an example encasing;

FIG. 8 shows an example encasing;

FIG. 9 shows an shows an example encasing;

FIG. 10 shows an example electronic device;

FIG. 11 shows an example electronic device;

FIG. 12 shows an example mold;

FIG. 13 shows an example method;

FIG. 14 shows an example method; and

FIG. 15 shows an example method.

### DETAILED DESCRIPTION OF ILLUSTRATIVE EMBODIMENTS

Disclosed herein are systems and methods for creating an encasing for one or more electronic devices. The systems and methods described herein may provide for efficient manufacturing of the encasing by injection molding. A sheet that includes ventilation apertures may be created by a process of injection molding using a cavity mold. The sheet may be formed into a shell for one or more electronic devices by overlapping or contacting a first end of the sheet to a second end of the sheet. A cavity for one or more electronic devices may be defined by coupling a first end cap and a second end cap to the shell. Such systems and methods may provide an effective way to manufacture encasings for electronic devices via injection molding, particularly by reducing cost and time requirements. The systems and methods may also enable the creation of a variety of apertures in the structure of the encasing during the injection molding process without the need to join multiple parts after the molding process.

In comparison, traditional processes for creating encasings with ventilation holes for electronic devices may involve multi-part and multi-mold processes. In some cases, a cylindrical encasing may be made by molding at least two parts of the cylinder and then later joining the two parts together. Ventilation holes may be added before or after the joining process by cutting away some of the joined parts. If the ventilation holes are desired to be made in the injection molding process, the required number of mold parts per encasing may increase significantly because every part may be removed (e.g., pulled) perpendicularly to the core of the mold. This traditional process of utilizing several tooling parts and a later joining step may be costly and time consuming, particularly where multi-cavity molds are used.

Further, the creation of ventilation holes in conventional mold processes may increase the likelihood of damaging the part upon removal of the mold. The number, location, and dimensions of ventilation holes created by a three-dimensional mold may increase the complexity in removing the part from the mold, and may facilitate damaging the part when attempting to pull the part away from the mold. Further, the location of ventilation holes in three-dimensional molding processes are typically limited. For example, as the material to be molded is typically in liquid form when placed in the mold, the volume and disposition of the liquid may be limited due to gravitational forces. When disposed in a three-dimensional mold, the liquid may rest in the mold unevenly, which may designed apertures partially defined. The systems and methods described herein address these issues.

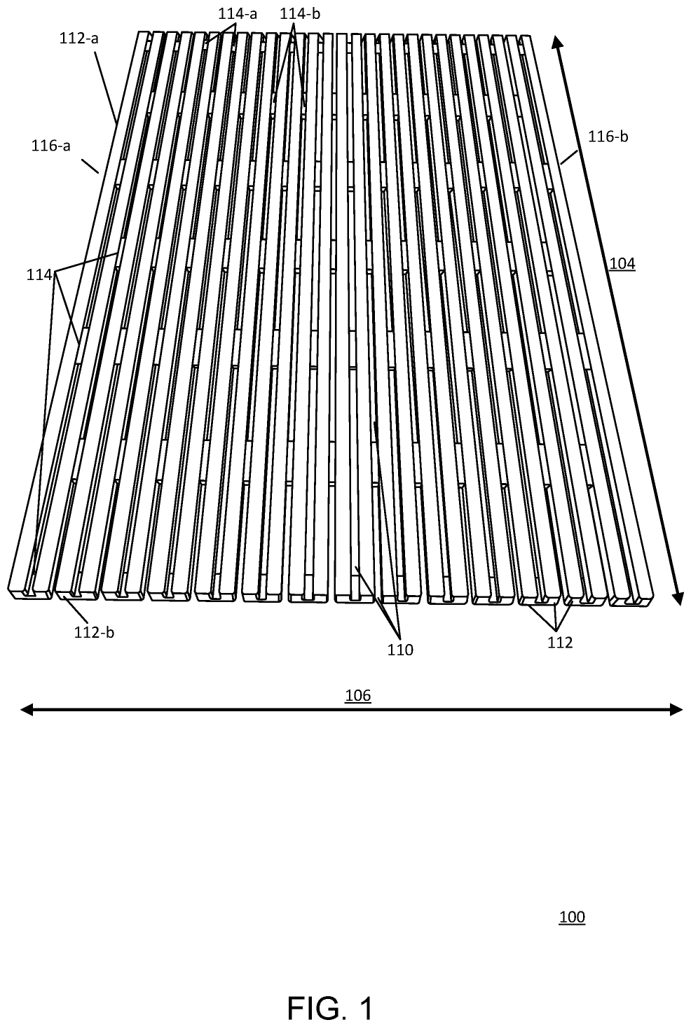

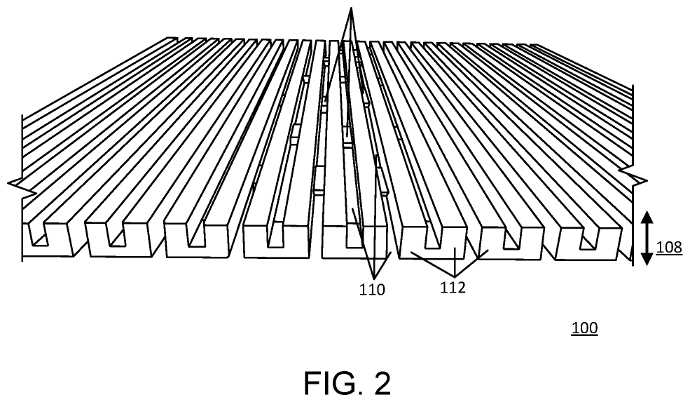

FIG. 1 depicts an isometric view of a sheet 100. The sheet 100 may be defined by a length dimension 104, a width dimension 106, and a height dimension 108 (shown in FIG. 2). Additionally, as is the case in FIG. 1, the sheet 100 may include one or more ventilation apertures 110. The sheet 100 may also define features such as cut-outs for buttons, cables, status indicators, speakers, and other input/output devices; attachment or securing mechanisms, some of which may be located on the outer surface of the sheet 100; and varying geometries along the length dimension 104, the width dimension 106, and the height dimension 108 of the sheet 100. In some cases, the sheet 100 may be, for example, a film, a page, a panel, a slab, a pane, a layer, a cover, a wrap, and the like.

FIG. 2 depicts an overhead view of the sheet 100, displaying a two-dimensional perspective of the features of sheet 100 located within the length dimension 104 and the width dimension 106. As noted above, the sheet 100 may include one or more ventilation apertures 110, which in some cases may run perpendicular to the width dimension 106 (e.g., along the length dimension 104). In some cases, the ventilation apertures may be defined to run along the width dimension 106 (e.g., perpendicular to the length dimension 104). The one or more ventilation apertures 110 may be defined by one or more vertical structures 112 and one or more connecting structures 114. The vertical structure 112 may be made from a plastic material, such as acrylic, acrylonitrile butadiene styrene (ABS), polypropylene, thermoplastic elastomer, thermoplastic urethane, flexible PVC, polycarbonate, nylon, and the like. Different materials may also be used, and one skilled in the art may select a plastic material based on considerations such as rigidity, cost, and time. Additionally, the material of the one or more connecting structures 114 may consist of the same material as the one or more vertical structures 112, or the two structures may consist of a different material. Furthermore, the material of the one or more vertical structures 112, along with the material of the one or more connecting structures 114, may vary within a sheet 100.

As depicted in FIG. 1, the vertical structures 112 may all have the same or similar physical dimensions throughout the sheet 100. In some cases, each vertical structure 112 (e.g., vertical structures 112-a and 112-b) has substantially the same length, width, and height dimension. Alternatively, the dimensions of the vertical structures 112 may vary throughout the sheet 100. For example, a variation may occur that creates a visibly predictable pattern, such as an alternation between two vertical structures 112 of two different lengths, two different widths (e.g., an “every other” pattern), or a combination thereof. In another example, a variation between the vertical structures 112 may occur in a random or pseudo-random pattern. Such a case may involve an assortment of vertical structures 112 in a sheet 100 that appear to be in a random arrangement (e.g., no perceivable pattern). In the pseudo-random case, the pattern may have a random appearance to general viewers, but the pattern may also be a definite and predictable design that is known to those who manufacture the sheet 100.

Additionally, as depicted in FIGS. 1 and 2, the one or more connecting structures 114 may follow a consistent pattern throughout the sheet 100. For example, a consistent pattern may include the insertion of a connecting structure 114 into the space between two vertical structures 112 in an “every other” pattern (e.g., every-other space between two vertical structures 112 contains a connecting structure 114). For example, connecting structures 114-a may be defined such that each connecting structure 114-a is positioned at similar positions along the width dimension 106 between corresponding vertical structures 112. Further, connecting structures 114-b may be defined such that each connecting structure 114-b is positioned at similar positions along the length dimension 106 between corresponding vertical structures 112. Likewise, connecting structures 114-a may be defined between vertical structures 112 different from the vertical structures defining the connecting structures 114-b. Other types of consistent patterns are possible, such as inserting a connecting structure 114 between every set of vertical structures 112. Furthermore, the location at which a connecting structure 114 is inserted along the length dimension 104 may be varied. For example, variation along the length dimension 104 may create a “step” pattern where the one or more connecting structures 114 appear to horizontally “step” up the sheet 100 between the one or more vertical structures 112. The one or more connecting structures 114 may also follow a random or pseudo-random pattern, as substantially described in the section pertaining to variations of the vertical structures 112.

Further, the dimensions of the connecting structures 114 may vary. For example, the dimensions of the connecting structures 114 may be increased or decreased to facilitate a shape desired for the sheet 100. For example, increasing the dimensions of the connecting structures 114 may facilitate increased structural rigidity for the sheet 100. Further, in some cases, the height or thickness of the connecting structures 114 may differ in relation to the corresponding vertical structures 112. For example, as depicted in FIG. 1, the thickness of the connecting structures 114 may be smaller than the thickness of the corresponding vertical structures 112 (e.g., in the height dimensions 108), such that the connecting structures 114 refrain from protruding from the sheet 100.

In some cases, the connecting structures 114 may be defined between the vertical structures 112. In some cases, the one or more connecting structures 114 may extend “outside” of the arrangement, or a portion of the arrangement, of vertical structures 112. For example, one or more vertical structures 112 may be located as the outermost structures of the sheet 100. Additionally, in some cases, the outermost structure of the sheet 100 may be a structure other than the one or more vertical structures and the one or more connecting structures 114.

In some cases, the vertical structures 112 located at the ends (e.g., in the width dimension 106) of sheet 100 may be designed to allow for attachment or overlap of one another. For example, one end (e.g., end 116-a) of sheet 100 may be defined by a vertical structure 112 and another other end (e.g., end 116-b) of sheet 100 may be defined by another vertical structure 112. In some cases, one end or both ends, may include (e.g., define) attachments for coupling to one another. Additionally, the design of the ends of the width direction 106 of sheet 100 may take into consideration surfaces that can be adhered, flushed, or a combination thereof, to one another. For example, one skilled in the art may design the surfaces for attachment or overlap such that a glue, epoxy, or the like, is able to effectively secure the attachment or overlap of those surfaces.

In some cases, the design that allows for attachment or overlap may include one or more securing mechanisms. For example, the design may incorporate a snap-fit assembly with one or more rocker arms or taper hooks on one end of the width direction 106 of sheet 100 and one or more joining partner structures on the other end such that the ends are able to lock into one another. In another example, an annular snap joint design may be used where one end of the width direction 106 of sheet 100 may include one or more ridge structures and the other end may include one or more groove structures that are able to lock into one another. In another example, the design may be of a “pin joint” or “pivot joint” in which joint ends may be placed at the ends of the width direction 106 of sheet 100 that can be secured by a pin. In another example where overlap of the sheet 100 is desired, holes or openings may be incorporated into the ends (or any portion of sheet 100) of the width direction 106 of sheet 100 such that nails, pins, or other securing mechanisms may be used to secure the overlap.

In some cases, the one or more vertical structures 112 located at the ends of the width direction 106 of sheet 100 may be designed to allow for a separate structure, not incorporated directly into sheet 100, to be attached to the sheet 100. For example, the design may allow for a backplate of an electronic device to be attached to sheet 100. In some cases, the design may be one of the aforementioned examples, such as incorporating ridge structures on both ends of the width direction 106 of sheet 100 and groove structures on the backplate such that both ends may be secured to the backplate.

In some cases, the maximum height dimension 108 of the sheet 100 may be constant along the width direction 106. Alternatively, the height of the vertical structures 112 may vary along the width dimension 106, thereby varying the overall height dimension 108 of the sheet 100. For example, the height of the vertical structures 112 may increase from each end of the width dimension 106 of the sheet 100 such that the middle of the width dimension corresponds with the maximum height dimension of the sheet 108. One skilled in the art will recognize that there are many ways to model the variation in height of the vertical structures 112 to produce a desired design of the height dimension of sheet 100.

In some cases, the height of the one or more vertical structures 112, the height of the one or more connecting structures 114, or a combination thereof, may be varied along the length dimension 104 of sheet 100. For example, the height of the one or more vertical structures may be decreased in a uniform fashion at the ends of the one or more vertical structures to create a fillet or chamfer feature.

The height of the one or more connecting structures 114 may be less than the height of the vertical structures 112. In other cases, the one or more connecting structures 112 may have a height equal to or greater than the vertical structures 112. Moreover, there may be cases where some, but not all, of the one or more connecting structures 112 have a height equal to or greater than the vertical structures 112. Variations in height of the one or more connecting structures 114 may be implemented along the lines of that described in the section regarding varying the height of the vertical structures 112.

Additionally, as is the case in FIG. 1C, the width dimension of the one or more vertical structures 112 and the width dimension of the one or more connecting structures 114 may be equal to one another, thereby creating a uniform spacing pattern. In other cases, the widths of one or both structures may be varied differently and/or create a non-uniform spacing pattern. Furthermore, the variations in width and height dimensions of these structures may be performed in conjunction with changes in the length dimension 108 of sheet 100.

The cross-sectional geometry of vertical structures 112 and one or more connecting structures 114 may incorporate a substantially rectangular shape. Alternatively, other cross-sectional geometries may be implemented into the structures of sheet 100. For example, the cross-sectional geometry of the one or more vertical structures 112 may include shapes that are circular, elliptical, polygonal, and the like. The same cross-sectional geometries may be used to create the one or more connecting structures 114.

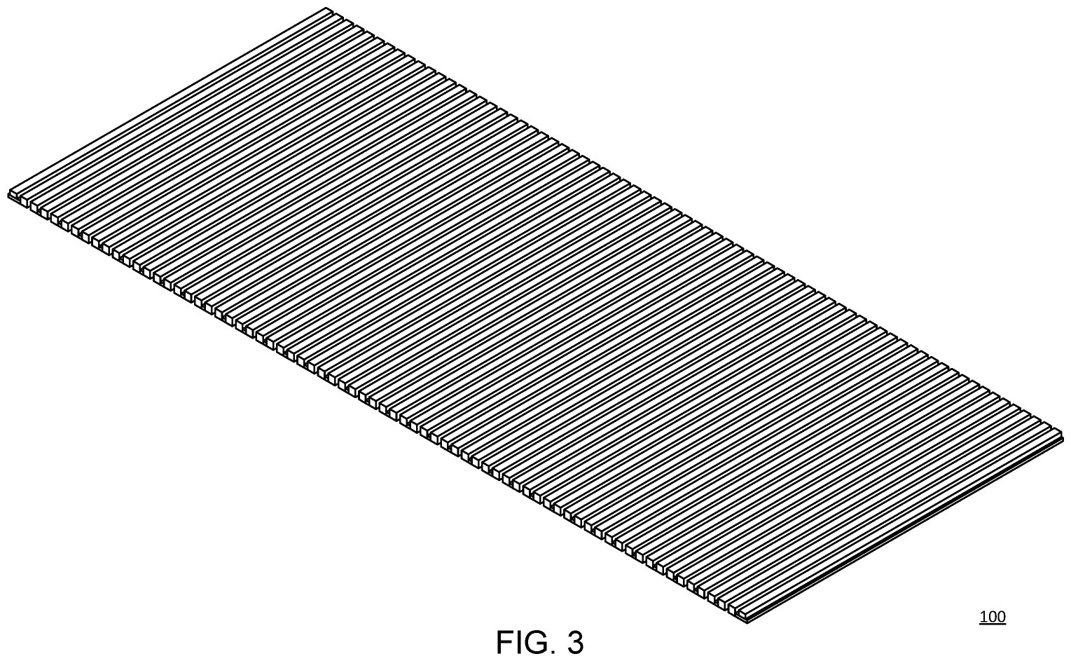

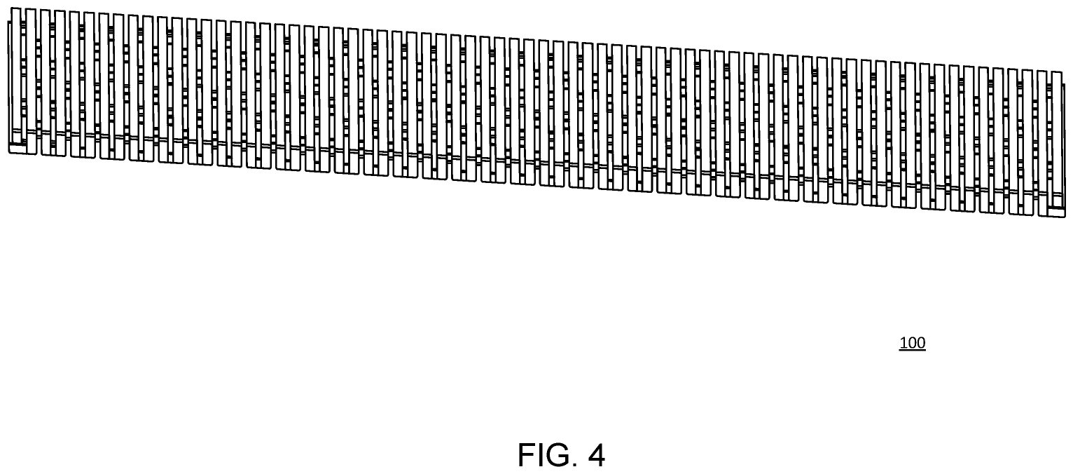

The aforementioned variations and examples of the sheet 100 may be desired for several reasons. For example, alterations to the size and spacing of the ventilation apertures may be desired to adjust the amount of ventilation. In another example, the length dimension 104 may be varied at the top or bottom of the sheet 100 to accommodate an opening or compartment, such as to allow for cables to pass through the sheet 100 or to incorporate an input/output component. Additionally. varying the dimensions of the vertical structures 112, the dimensions of the one or more connecting structures 114, or a combination thereof, may be desired to increase the physical performance of the sheet, such as in structural rigidity. Alternatively, or in addition to performance considerations, variations may be desired for aesthetic purposes. FIGS. 3 and 4 depict other perspective views of the sheet 100.

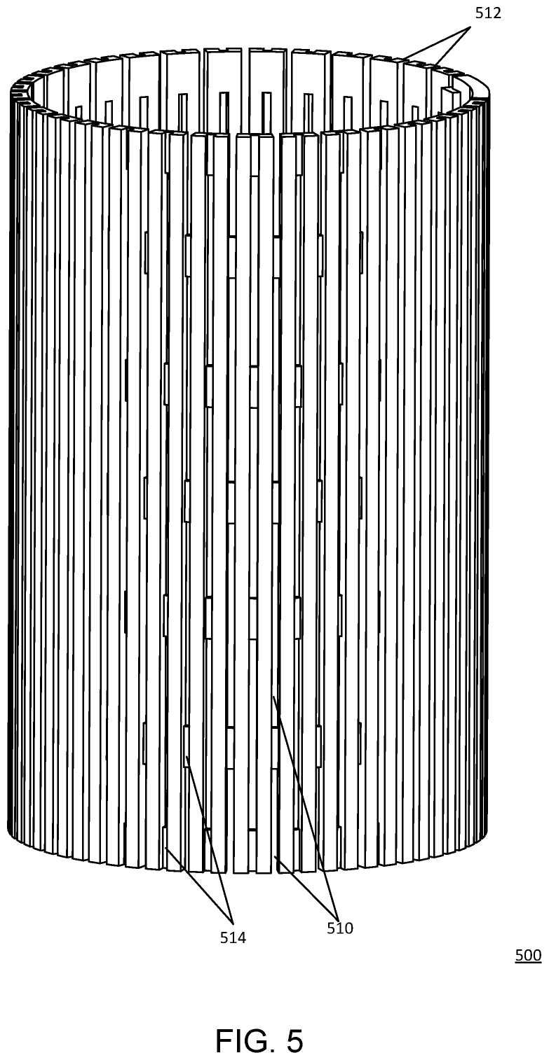

FIG. 5 depicts an isometric view of a shell 500. The shell 500 may incorporate a version of the sheet 100 described with respect to FIGS. 1-4. The shell 500 may define one or more ventilation apertures 510, and may include one or more vertical structures 512 and one or more connecting structures 514, such as, or similar to, those found in the descriptions and figures of sheet 100.

In some cases, the shape of the shell 500 may be substantially cylindrical. In other cases, the shape of the shell may be formed into different shapes by varying the dimensions of the sheet 100 as discussed in more detail above.

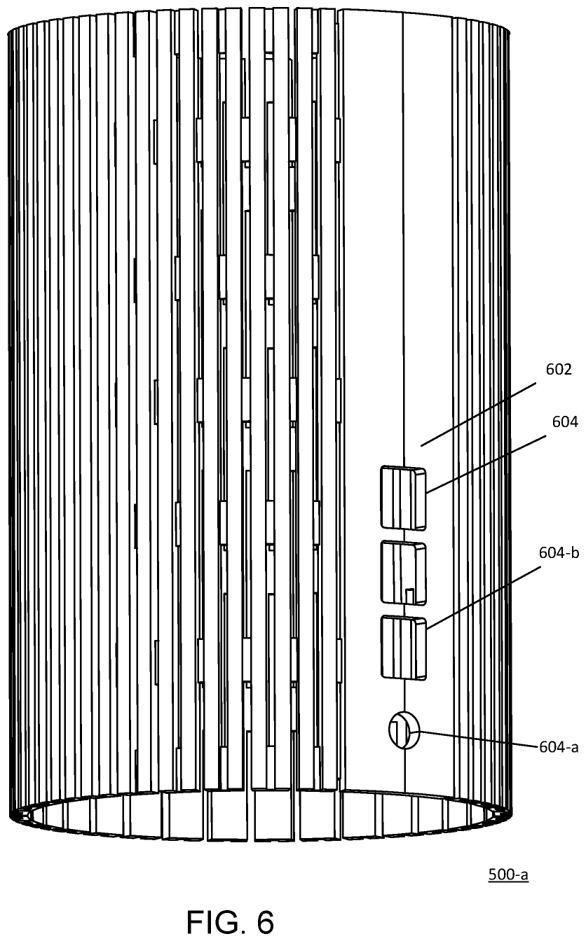

In some cases, the shell may define additional apertures apart from the ventilation apertures described above. For example, FIG. 6 depicts an isometric view of a shell 200-a. The shell 200-a may include solid structure 602. In some cases, the shell 200-a may incorporate more than one solid structure 602. Furthermore, the design of the solid structures does not need to be identical to one another.

The solid structure 602 may be incorporated into the shell 200-a by including it in a sheet 100 used to make the shell 200-a. The sheet may incorporate the solid structure 602 by splitting the design of the solid structure 602 into halves and locating the design of each half on opposite ends of the sheet 100 (e.g., ends 116-a and 116-b of FIG. 1). Alternatively, the sheet 100 may incorporate the solid structure 602 by placing the complete design of the solid structure 602 on one end of the sheet 100. In other cases, the solid structure 602 may be incorporated into the shell 200-a by means other than by including it in a sheet 100, such as adding the solid structure 602, as a separate component, in conjunction with a sheet that may be included in the shell 200-a.

In some cases, the solid structure 602 may include one or more openings 604. For example, the solid structure 602 may include one or more openings for a circular shape 604-a and a rectangular shape 604-b. In other cases, different shapes may be incorporated as the one or more opening 604. Additionally, the number of the one or more openings 604 may vary depending on the function and aesthetics of the shell 200-a. Furthermore, the one or more openings 604 may be located anywhere within the solid structure 602.

One or more openings 604 may be particularly desirable to allow for physical items, heat, and sound to pass through the shell 200-a. For example, when the shell 200-a is used as an encasing for an electronic device, the shell 200-a may have openings to allow for a power cord; input and output devices; and other physical items to pass through the encasing and connect to the electronic device. Additionally, one or more openings 604 in a shell 200-a may be used to allow active or passive ventilation from the environment outside of the shell 200-a and the environment inside the shell 200-a. In such cases, the ventilation may be to facilitate heat transfer from one or more electronic devices inside the shell 200-a to the environment outside of the shell 200-a. Furthermore, the one or more openings 604 may allow for sound, radio, and infrared waves to efficiently pass from inside the shell 200-a to sources outside of the shell 200-a. From a non-functional perspective, the one or more openings 604 in the structure of the encasing may also be desired for aesthetic purposes.

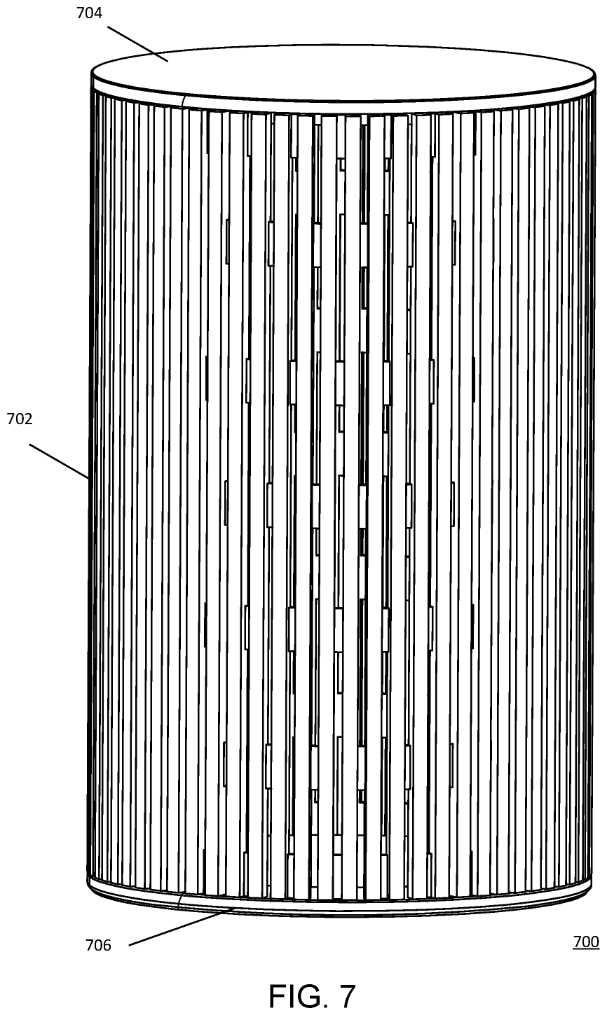

FIG. 7 depicts an isometric view of an enclosure 700. In some cases, the enclosure 700 may be referred to as “an encasing,” “an encasing for an electronic device,” and the like. The enclosure 700 may be partially defined by a shell 702, such as the shell 200 or the shell 200-a depicted and described above. The enclosure may be further defined by a first end cap 704 and a second end cap 706. The first end cap 704 and the second end cap 706 may be of identical design. In other cases, the two end caps may be of a different design. For example, one, or both end caps may include a substantially planar shape. In other cases, one or both endcaps may include a three-dimensional shape (e.g., a dome or partial dome).

In some cases, the first end cap 704, the second end cap 706, or a combination thereof, may be secured to the shell 702, which may be an example of shell 500 or 500-a. Securing may be performed through similar means to the securing mechanisms of sheet 100 described above. For example, securing may be performed by an adhesive, such as glue or epoxy. In another example, securing means may be implemented into the top and bottom of the shell 702 and the corresponding sections on the first end cap 704 and the second end cap 706 such that the end caps are secured to the shell 702. The securing mechanisms may be implemented directly into the components (e.g., in an injection molding design of a sheet that will be used to create the shell 702) or implemented after the manufacture of the components.

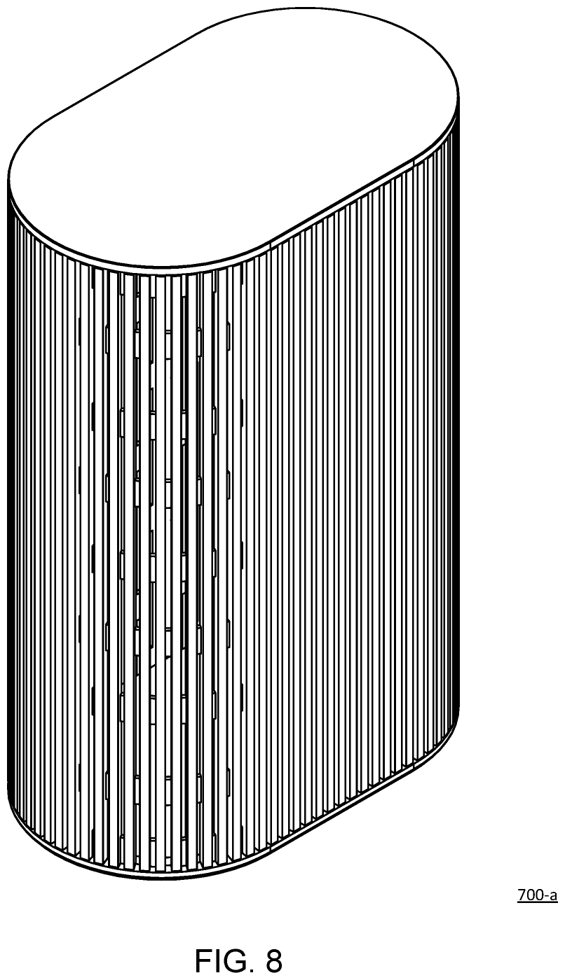

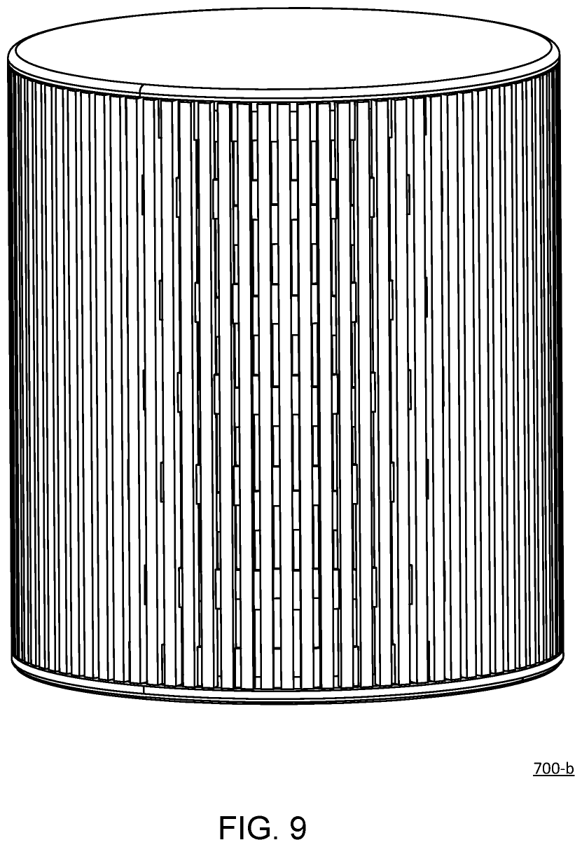

FIG. 8 depicts an isometric view of an enclosure 700-a. Similar to the enclosure 700, the enclosure 700-a may be partially defined by a shell, a first end cap, and a second end cap. The first end cap and second end cap may resemble a surface in the shape of a “slot” or “pill.” In other cases, the first end cap and second end cap may resemble other surface geometries, such as a square, rectangle, hexagon, octagon, and the like. Furthermore, more complex surface geometries are possible, such as curving the shape of the “slot” or “pill” surface of the first end cap and the second end cap. The shape of the first and second end cap may define the cross-sectional area of the enclosure 700-a such that the shell conforms to the shape of the first and second end caps. FIG. 9 depicts another example of an enclosure 700-b, where the enclosure is in the shape of a drum (e.g., with circular end caps).

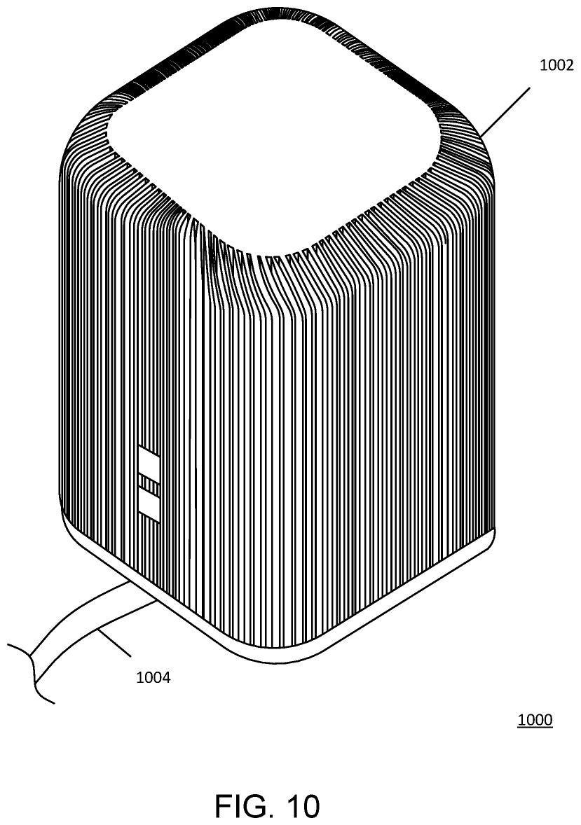

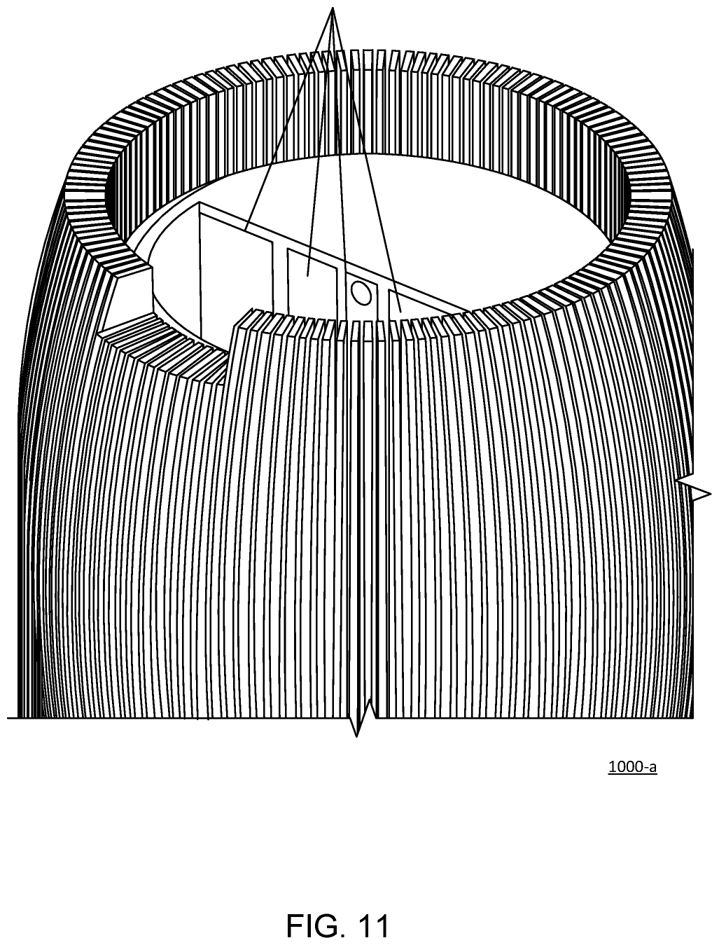

FIG. 10 depicts an isometric view of an encasing for an electronic device 1000. The encasing for an electronic device 100 may include an enclosure 1002, which may be an example of the enclosures 700-700-b described with reference to FIGS. 7-9. The enclosure 1002 may be used to house one or more electronic components 1004, which are depicted in FIG. 11. The one or more electronic components 1104 may include wires, resistors, diodes, LEDs, transformers, batteries, and the like. The one or more electronic components 1004 may be located on one or more electronic devices, such as a PCBs, router, speaker, display panel, tablet, and the like.

The enclosure 1002 may be partially defined by a shell, such as shell 500 or 500-a of FIG. 5 or 6, respectively. The shell may be made from a sheet, such as sheet 100 described in FIGS. 1-4. In some cases, the shell may include a filleted edge. The filleted edge may have been integrated directly into the design of the sheet. Alternatively, the filleted edge may have been made by a post-molding finishing process, such as cutting away or grinding away material from a sheet. Furthermore, the shell may include a rectangular edge (e.g., not filleted or otherwise modified).

The shell may define one or more openings. The one or more openings may have been integrated into the design of a sheet, such as the design found and described in FIG. 6. The one or more openings may have been cut away from a uniform sheet design. Additionally, the one or more openings may have been cut away from the shell.

The enclosure 1002 may be partially defined by a first end cap and a second end cap. The first end cap may be secured from “within” or beneath the filleted edge of the shell. For example, the first end cap may be inserted through a bottom aperture of the shell, where the second end cap is located, to contact an upper aperture of the shell, where the filleted edge is located. The first end cap may be shaped such that it is substantially flat over an area corresponding to the edge of the filleted edge of the shell and curved to match the filleted edge of the shell over that section. In other cases, the first end cap may be secured from the outside of the shell. For example, the first end cap may be secured by placing the first end cap over the filleted edge.

In some cases, the second end cap may be secured flush with the rectangular edge. In other cases, the second end cap may be larger than the outer surface of the rectangular edge. In other cases, the second end cap may include an inner bezzle that is slightly smaller than the outer surface of the rectangular edge such that when the bezzle is inserted within the outer surface of the rectangular edge, the second end cap is substantially secured.

In some cases, the an end cap may define one or more openings in its structure. The one or more openings may allow for physical access to the enclosure 1002. For example, the one or more openings may allow a power cable 1004 to extend from outside the encasing to the enclosure 1002 and deliver power to one or more electronic devices located therein. In other cases, the one or more openings may allow for ventilation, transmission of signals or sound, or a combination thereof. FIG. 11 depicts another view of an electronic device 1000-a, where the electronic components 1102 may be viewed.

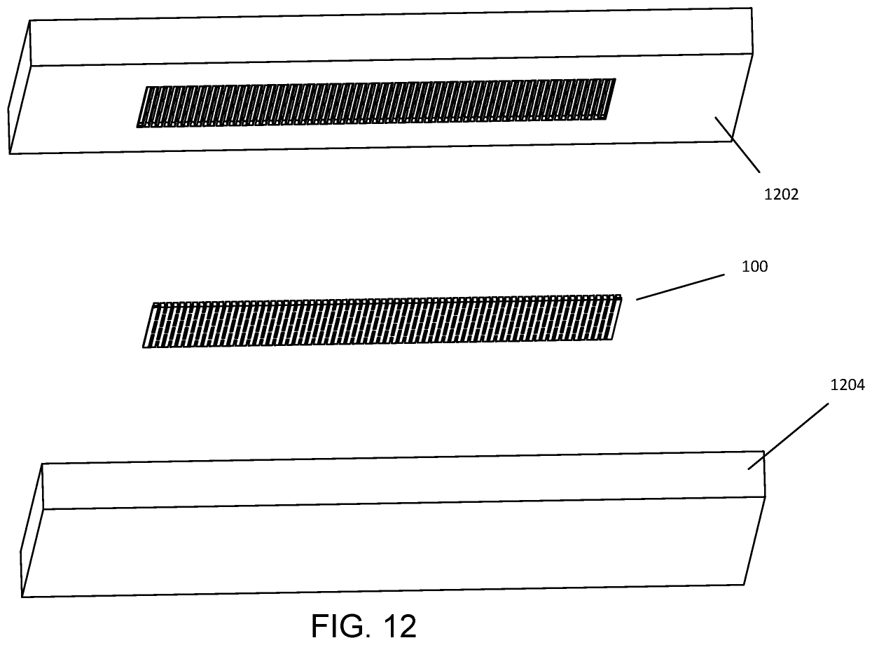

FIG. 12 depicts an isometric view of an injection molding system 1200 according to the present disclosure. The injection molding system may be configured to create or generate a sheet, such as sheet 100, for the electronic devices described herein. The injection molding system 1200 may include an injection mold, which may include a first mold portion 1202 and a second mold portion 1204. The first mold portion 1202 may define, on a face, a cavity. For example, the first mold portion 1202 may define a series of ridges and valleys, which may be configured to retain a volume of curable liquid. In some cases, the second mold portion 1204 may define a corresponding cavity (e.g., ridges and valleys) that, when disposed flush to the cavity of the first mold portion 1202, may form the general shape of a sheet (e.g., sheet 100). In some cases, the second mold portion 1204 may define a flat surface, such that the entire volume of the sheet is defined by the first mold portion.

A volume of curable liquid may be disposed in the cavity defined by the first mold portion 1202 and the second mold portion 1204. The first mold portion 1202 and the second mold portion 1204 may be positioned to be flush with one another. In some cases, the first mold portion 1202, the second mold portion 1204, or both, may be injection mold portions, which may define access points for the volume of liquid to flow or be input to the cavity when the mold portions are flush with one another.

The volume of curable liquid may be allowed to cure for a period of time (e.g., which may be dependent on the volume of liquid, the composition of the liquid, ambient temperature, and the like). In some cases, the volume of liquid may be a thermos-curable, and thus heat may be applied to the mold system 1200 during the curing process.

The mold portions may be moved away from each other to expose the volume in the cavity. In some cases, the volume may be fully cured to form a solid sheet (e.g., sheet 100). In some cases, the volume may be partially cured (e.g., in a semi-solid state), which may facilitate the wrapping and forming of the shell.

The volume in the cavity may be removed from the mold. In some cases, removal may be performed manually, where a user physically pulls the volume from the mold. As the volume is shaped in substantially a two-dimensional sheet, removal from the mold may be less complex as compared to conventional three-dimensional mold processes, and may reduce the risk of tearing, breaking, or deforming the volume upon removal.

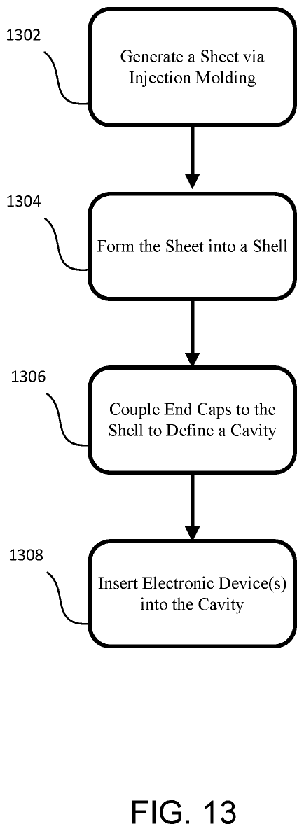

FIG. 13 shows an example method. At step 1302, a sheet may be generated using injection molding techniques. Injection molding techniques may include utilizing an injection molding system 1200, shown and described in the section overviewing FIG. 12. The sheet may be any of the aforementioned sheet designs. For example, the sheet may be sheet 100. In some cases, the sheet may be generated from a single cavity mold tool. In other cases, a multi cavity tooling may be used to generate multiple sheets in a single cycle. The multiple sheets may be of the same or different sheet geometry. Furthermore, family tools may be used to generate the sheet and any other components (e.g., end cap geometries) in a single mold cycle.

At step 1304, the sheet may be formed into a shell. Forming the sheet into a shell may include wrapping the sheet into a cylindrical shape such that there is overlapping or contacting of a first end of the sheet to a second end of the sheet. Forming the sheet into a shell may include shaping the sheet into other various shapes, such as a triangle, square, hexagon, ellipse, and the like. Furthermore, forming the shell may include securing a first end of the sheet to a second end of the sheet by means of a securing mechanism, such as those described above.

At step 1306, a cavity may be defined by coupling one or more end caps to the shell. Coupling one or more end caps may include securing a first end cap and a second end cap to opposite ends of the shell, such as that described in the section overviewing FIGS. 7-9. Furthermore, coupling one or more end caps to the shell may include securing the one or more end caps to the shell by one or more securing mechanisms described above.

At step 1308, electronic components may be inserted into the defined cavity. For example, electronic components may include processing or memory components, receiver/transmitter components, power components, and the like.

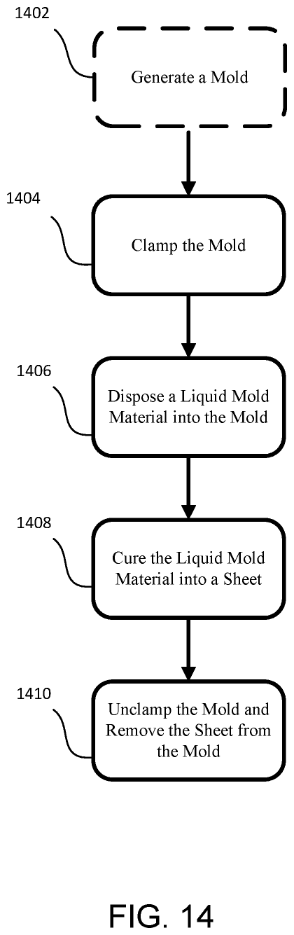

FIG. 14 shows an example method. At step 1402, a mold may be generated. In some cases, generating the mold may include fabricating a mold tool that includes an injection mold (“A plate” or “mold cavity”) and an ejector mold (“B plate” or “mold core”). In a similar design to that of the injection mold system 1200 in FIG. 12, the mold tool may be designed such that when the mold is in a “closed” position, one or more cavities are formed between the injection mold and the ejector mold. The one or more cavities may define the shape of a sheet, such as those described above. Additionally, the design of the injection mold may also include a sprue, connected to channels that are directed to one or more cavities. Furthermore, the design of either or both the injection mold or the ejector mold cooling channels may include cooling channels. The injection mold and the ejector mold may be made from several different materials, such as steel, aluminum, nickel, or epoxy. The injection mold and the ejector mold may be fabricated by several manufacturing processes, such as computer numeric code (“CNC”) machining or electrical discharge machining (“EDM”). In some cases, step 1402 may be optional, particularly where a mold has already been generated.

At step 1404, a clamping force may be applied to the mold. The clamping force may be such that the injection mold and the ejector mold of step 1000 may be secured together (e.g., the mold is in the “closed” position). Additionally, the clamping force may be such that the cavity of the mold is sealed to a point at which liquid is unable to escape the cavity of the mold when under pressure. The clamping force may be generated by a clamping unit of an injection molding machine, which may include a driving mechanism for moving the injection mold and the ejector mold relative to one another and delivering a clamping force to keep the mold closed.

At step 1406, a liquid mold material may be disposed into the mold. Disposing the liquid mold material into the mold may include using a nozzle to disperse molten plastic through a sprue. The sprue may connect to channels within the mold that may be used to fill the one or more cavities of the mold. Disposing the liquid mold material into the mold may be performed by an injection unit of the injection molding machine. The injection unit may include components such as a hopper, heating element, mobilizing element, nozzle, or a combination thereof. In some cases, a raw mold material may move the hopper to the mobilizing element which may advance the raw mold material through the heating element. In some cases, the injection unit may then inject the liquid mold material into the mold. In some cases, the liquid mold material may fill the one or more cavities of the mold.

At step 1408, a sheet may be cured from the liquid mold material. In some cases, curing the sheet may include allowing the molten plastic to harden. For example, allowing the molten plastic to harden may involve cooling the liquid mold into a solid, or substantially solid, form.

At step 1410, the sheet may be removed from the mold. Removing the sheet from the mold may include utilizing ejection components of the injection molding machine. Additionally, post-processing, such as trimming excess material from the sheet, may also be performed.

Modifications of the above example injection molding process, along with other types of injection molding processes, are able to be utilized in accordance with the present invention. For example, the above example injection molding process may be modified such that the clamping unit or mold assembly includes an ejection mechanism that pushes the molded part out of the mold. Additionally, a mold release agent may be sprayed into the mold assembly to facilitate the ejection of the part. Furthermore, the injection molding machine may be arranged in different configurations, such as horizontal and vertical. As such, it is understood that a person skilled in the art would understand how to adopt such example injection molding process modifications, along with the general class of injection molding processes, to be utilized in accordance with the present invention.

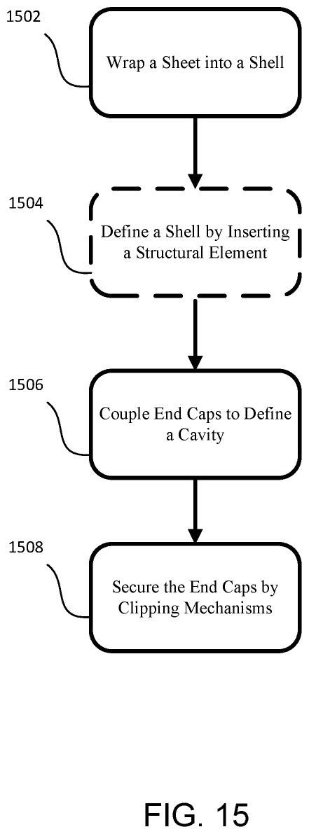

FIG. 15 shows an example method. At step 1502, a sheet may be wrapped into a shape. The shape may be cylindrical, such as those found in FIG. 5-7. The shape may be in the shape of a “slot” or “pill,” such as that found in FIG. 8. The shape may be rectangular, such as that found in FIG. 10. Additionally, the shape may be any of the aforementioned shapes described in prior sections. The shape may be such that it is an “incomplete” or “partially open” shape.

At step 1504, a structural element may optionally be inserted into the sheet wrapped into a shape to define a shell. Inserting the structural element may include contacting a first end of the sheet with a first end of the structural element and a second end of the sheet with a second end of the structural element. It may also include securing surfaces of the sheet with surfaces of the structural element using a securing mechanism, as described above. The structural element may include one or more cut-outs, similar to that shown and described in FIG. 6. Additionally, multiple structural elements may be inserted into the sheet (or, in the case of multiple sheets, inserted between the multiple sheets wrapped into a shape).

At step 1506, a cavity may be defined by coupling one or more end caps. Coupling one or more end caps may include arranging end caps on the shell, such as those shown in FIGS. 7-9. In other cases, coupling one or more end caps may include performing any of the aforementioned descriptions of the prior sections.

At step 1508, one or more clipping mechanisms may be used to secure the end caps to the shell. The one or more clipping mechanisms may be similar to that described in the sections overviewing FIGS. 7-9. Furthermore, in some cases, the one or more clipping mechanisms may be replaced by other securing means, such as adhesive or using a compliant design of the end caps and shells to fit securely with one another. Optionally, either before or after the end caps have been secured, one or more electronic devices, components, or a combination thereof may be inserted into the cavity.

The aforementioned systems and methods may be implemented for several reasons. For example, encasings for electronic devices may implement one or more openings in the structure of the encasing to allow for physical items, heat, and sound to pass through the encasing and to the electronic device. For example, an encasing for an electronic device may have openings to allow a power cord; input and output devices; and other physical items to pass through the encasing and connect to the electronic device. Additionally, an encasing for an electronic device may implement openings in the encase to allow active or passive ventilation that facilitate heat transfer from the electronic device to the environment outside of the encasing. Furthermore, an encasing for an electronic device may have openings to allow for sound, radio, and infrared waves to efficiently pass from the electronic device to sources outside of the encasing. From a non-functional perspective, openings in the structure of the encasing may also be desired for aesthetic purposes.

It is to be understood that the methods and systems described herein are not limited to specific methods, specific components, or to particular implementations. It is also to be understood that the terminology used herein is for the purpose of describing particular embodiments only and is not intended to be limiting.

As used in the specification and the appended claims, the singular forms “a,” “an,” and “the” include plural referents unless the context clearly dictates otherwise. Ranges may be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

“Optional” or “optionally” means that the subsequently described event or circumstance may or may not occur, and that the description includes instances where said event or circumstance occurs and instances where it does not.

Throughout the description and claims of this specification, the word “comprise” and variations of the word, such as “comprising” and “comprises,” means “including but not limited to,” and is not intended to exclude, for example, other components, integers or steps. “Exemplary” means “an example of” and is not intended to convey an indication of a preferred or ideal embodiment. “Such as” is not used in a restrictive sense, but for explanatory purposes.

Components are described that may be used to perform the described methods and systems. When combinations, subsets, interactions, groups, etc., of these components are described, it is understood that while specific references to each of the various individual and collective combinations and permutations of these may not be explicitly described, each is specifically contemplated and described herein, for all methods and systems. This applies to all aspects of this application including, but not limited to, operations in described methods. Thus, if there are a variety of additional operations that may be performed it is understood that each of these additional operations may be performed with any specific embodiment or combination of embodiments of the described methods.

The present methods and systems may be understood more readily by reference to the following detailed description of preferred embodiments and the examples included therein and to the Figures and their descriptions.

As will be appreciated by one skilled in the art, the methods and systems may take the form of an entirely hardware embodiment, an entirely software embodiment, or an embodiment combining software and hardware aspects. Furthermore, the methods and systems may take the form of a computer program product on a computer-readable storage medium having computer-readable program instructions (e.g., computer software) embodied in the storage medium. More particularly, the present methods and systems may take the form of web-implemented computer software. Any suitable computer-readable storage medium may be utilized including hard disks, CD-ROMs, optical storage devices, or magnetic storage devices.

Embodiments of the methods and systems are described herein with reference to block diagrams and flowchart illustrations of methods, systems, apparatuses and computer program products. It will be understood that each block of the block diagrams and flowchart illustrations, and combinations of blocks in the block diagrams and flowchart illustrations, respectively, may be implemented by computer program instructions. These computer program instructions may be loaded on a general-purpose computer, special-purpose computer, or other programmable data processing apparatus to produce a machine, such that the instructions which execute on the computer or other programmable data processing apparatus create a means for implementing the functions specified in the flowchart block or blocks.

These computer program instructions may also be stored in a computer-readable memory that may direct a computer or other programmable data processing apparatus to function in a particular manner, such that the instructions stored in the computer-readable memory produce an article of manufacture including computer-readable instructions for implementing the function specified in the flowchart block or blocks. The computer program instructions may also be loaded onto a computer or other programmable data processing apparatus to cause a series of operational steps to be performed on the computer or other programmable apparatus to produce a computer-implemented process such that the instructions that execute on the computer or other programmable apparatus provide steps for implementing the functions specified in the flowchart block or blocks.

The various features and processes described herein may be used independently of one another, or may be combined in various ways. All possible combinations and sub-combinations are intended to fall within the scope of this disclosure. In addition, certain methods or process blocks may be omitted in some implementations. The methods and processes described herein are also not limited to any particular sequence, and the blocks or states relating thereto may be performed in other sequences that are appropriate. For example, described blocks or states may be performed in an order other than that specifically described, or multiple blocks or states may be combined in a single block or state. The example blocks or states may be performed in serial, in parallel, or in some other manner. Blocks or states may be added to or removed from the described example embodiments. The example systems and components described herein may be configured differently than described. For example, elements may be added to, removed from, or rearranged compared to the described example embodiments.

It will also be appreciated that various items are illustrated as being stored in memory or on storage while being used, and that these items or portions thereof may be transferred between memory and other storage devices for purposes of memory management and data integrity. Alternatively, in other embodiments, some or all of the software modules and/or systems may execute in memory on another device and communicate with the illustrated computing systems via inter-computer communication. Furthermore, in some embodiments, some or all of the systems and/or modules may be implemented or provided in other ways, such as at least partially in firmware and/or hardware, including, but not limited to, one or more application-specific integrated circuits (“ASICs”), standard integrated circuits, controllers (e.g., by executing appropriate instructions, and including microcontrollers and/or embedded controllers), field-programmable gate arrays (“FPGAs”), complex programmable logic devices (“CPLDs”), etc. Some or all of the modules, systems, and data structures may also be stored (e.g., as software instructions or structured data) on a computer-readable medium, such as a hard disk, a memory, a network, or a portable media article to be read by an appropriate device or via an appropriate connection. The systems, modules, and data structures may also be transmitted as generated data signals (e.g., as part of a carrier wave or other analog or digital propagated signal) on a variety of computer-readable transmission media, including wireless-based and wired/cable-based media, and may take a variety of forms (e.g., as part of a single or multiplexed analog signal, or as multiple discrete digital packets or frames). Such computer program products may also take other forms in other embodiments. Accordingly, the present invention may be practiced with other computer system configurations.

While the methods and systems have been described in connection with preferred embodiments and specific examples, it is not intended that the scope be limited to the particular embodiments set forth, as the embodiments herein are intended in all respects to be illustrative rather than restrictive.

Unless otherwise expressly stated, it is in no way intended that any method set forth herein be construed as requiring that its operations be performed in a specific order. Accordingly, where a method claim does not actually recite an order to be followed by its operations or it is not otherwise specifically stated in the claims or descriptions that the operations are to be limited to a specific order, it is no way intended that an order be inferred, in any respect. This holds for any possible non-express basis for interpretation, including: matters of logic with respect to arrangement of steps or operational flow; plain meaning derived from grammatical organization or punctuation; and the number or type of embodiments described in the specification.

It will be apparent to those skilled in the art that various modifications and variations may be made without departing from the scope or spirit of the present disclosure. Other embodiments will be apparent to those skilled in the art from consideration of the specification and practices described herein. It is intended that the specification and example figures be considered as exemplary only, with a true scope and spirit being indicated by the following claims.

What is claimed:

1. A method for manufacturing a housing for an electronic device, comprising:
generating, via injection molding, a sheet defining:
a length dimension;
a width dimension; and
one or more ventilation apertures running along the width dimension;
forming the housing of the electronic device by overlapping or contacting a first end of the sheet to a second end of the sheet; and
coupling a first end cap and a second end cap to the shell to define a cavity.

2. The method of claim 1, further comprising:
disposing one or more electronic components within the cavity.

3. The method of claim 1, wherein generating the sheet further comprises:
disposing a volume of liquid within a mold; and
solidifying the volume of liquid to form the sheet.

4. The method of claim 3, wherein the mold comprises a single-cavity mold.

5. The method of claim 1, wherein the first edge and the second edge are each defined along the width dimension of the sheet.

6. The method of claim 1, wherein the first endcap and the second endcap couple to respective edges of the sheet defined along the length dimension of the sheet.

7. The method of claim 1, wherein at least one of the one or more ventilation apertures extends along an entire width of the sheet.

8. The method of claim 1, wherein the electronic device comprises a gateway, a router, a mesh node, or a combination thereof.

9. The method of claim 1, wherein the sheet further defines a thickness dimension, and wherein the thickness dimension varies in size along the length or width dimensions.

10. The method of claim 9, further comprising:
coupling the first end of the sheet to the second of the sheet via a clipping mechanism, or coupling the first endcap or the second endcap to the sheet via a clipping mechanism.

11. The method of claim 1, wherein the sheet is planar along the length dimension and the width dimension.

12. The method of claim 1, wherein the sheet forms a polygon.

13. The method of claim 1, wherein the one or more ventilation apertures comprises a plurality of ventilation apertures, and wherein the ventilation apertures are defined to be equally spaced from one another along the length dimension.

14. The method of claim 1, wherein the housing forms a cylindrical shape.

15. The method of claim 1, wherein the housing defines an opening configured to receive a separate structural element.

16. The method of claim 15, wherein the separate structural element is a backplate that defines one or more openings for a power cable, one or more buttons, one or more lights, or a combination thereof.

17. The method of claim 15, wherein the separate structural element is a display panel for the electronic device.

18. The method of claim 1, wherein the sheet defines one or more clipping mechanisms positioned adjacent to an edge defined by the sheet.

19. The method of claim 18, wherein the first endcap, the second endcap, or both, are coupled to the sheet by the one or more clipping mechanisms.

20. The method of claim 1, wherein the first endcap, the second endcap, or both, defines cut-outs for ventilation of the electronic device.
